(19) United States
(12) Patent Application Publication
(10) Pub. No.: US 2026/0096182 A1
(43) Pub. Date: Apr. 2, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Hsueh-Ju CHEN, Taipei (TW); Chun-Yen PENG, Hsinchu (TW); Tsung-Da LIN, Hsinchu (TW); Chi On CHUI, Hsinchu (TW)

(21) Appl. No.: 19/015,920

(22) Filed: Jan. 10, 2025

Related U.S. Application Data
(60) Provisional application No. 63/700,710, filed on Sep. 29, 2024.

(51) Int. Cl. H10D 64/66; H10D 30/00; H10D 30/01; H10D 30/43; H10D 62/10

(52) U.S. Cl. CPC H10D 64/665; H10D 30/014; H10D 30/019; H10D 30/43; H10D 30/501; H10D 62/121

(57) ABSTRACT

Embodiments of the present disclosure provide a semiconductor device structure and methods for forming the same. The structure includes a first semiconductor layer, a second semiconductor layer disposed over the first semiconductor layer, a gate dielectric layer disposed between the first and second semiconductor layers, and first and second regions of a dielectric material disposed on opposite sides of the gate dielectric layer. The first region of the dielectric material includes a first metal, and a concentration of the first metal in the first region decreases in a direction towards the gate dielectric layer. The structure further includes first and second dielectric spacers, and the gate dielectric layer and the first and second regions of the dielectric material are disposed between the first and second dielectric spacers.

### CROSS-REFERENCE TO RELATED APPLICATIONS

This application claims priority to U.S. Provisional Application Ser. No. 63/700,710 filed Sep. 29, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure, in accordance with some embodiments.

FIGS. 6, 7, 8, 9, 10, 11, 12, 13, 14, 15, and 16 are cross-sectional side views of the semiconductor device structure taken along line A-A of FIG. 5, in accordance with some embodiments.

FIGS. 17, 18, 19, and 20 are cross-sectional side views of the semiconductor device structure taken along line A-A of FIG. 5, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as Horizontal Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

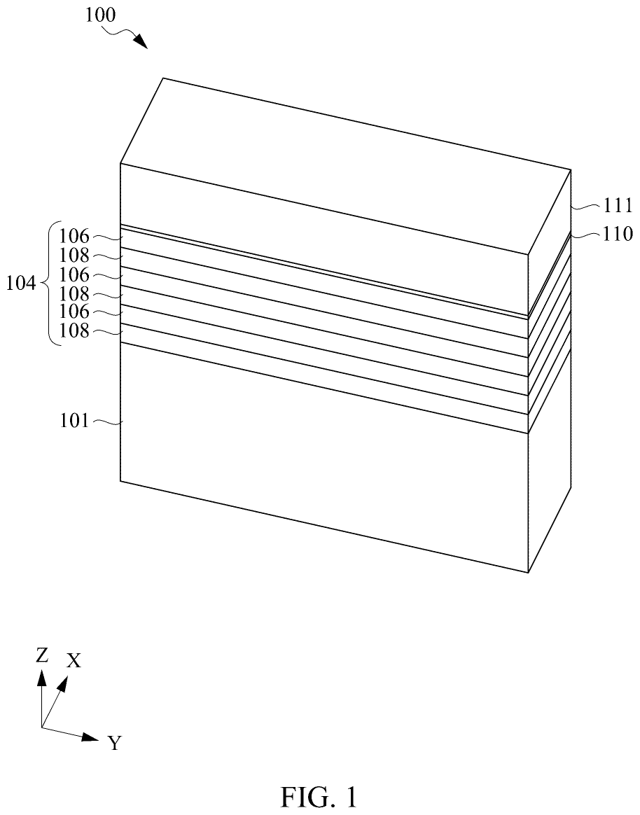

FIGS. 1-16 show exemplary processes for manufacturing a semiconductor device structure 100 according to embodiments of the present disclosure. It is understood that additional operations can be provided before, during, and after processes shown by FIGS. 1-16, and some of the operations described below can be replaced or eliminated, for additional embodiments of the method. The order of the operations/processes is not limiting and may be interchangeable.

FIGS. 1, 2, 3, 4, and 5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP).

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

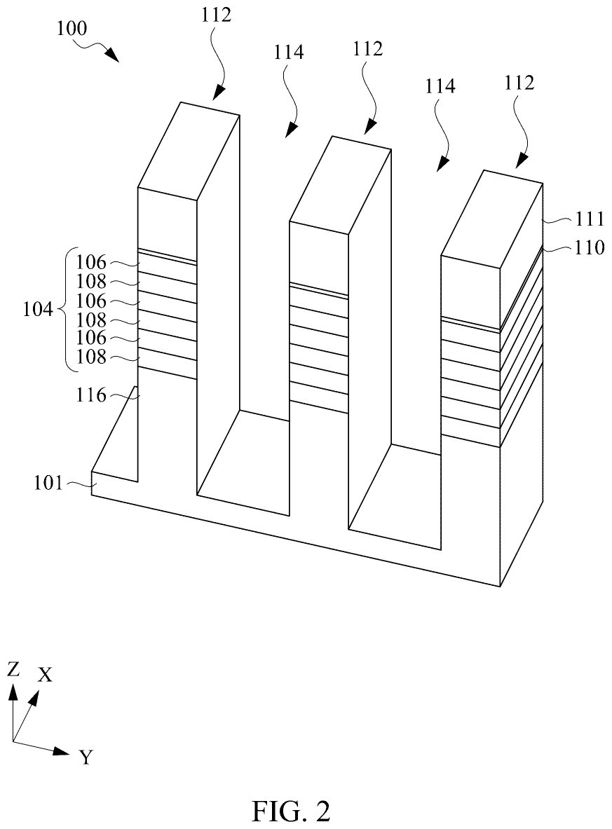

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

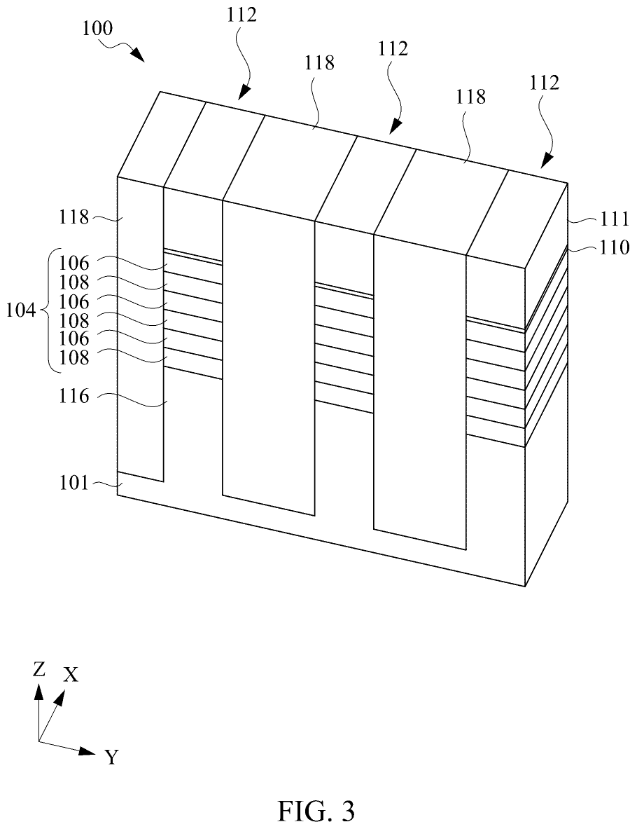

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

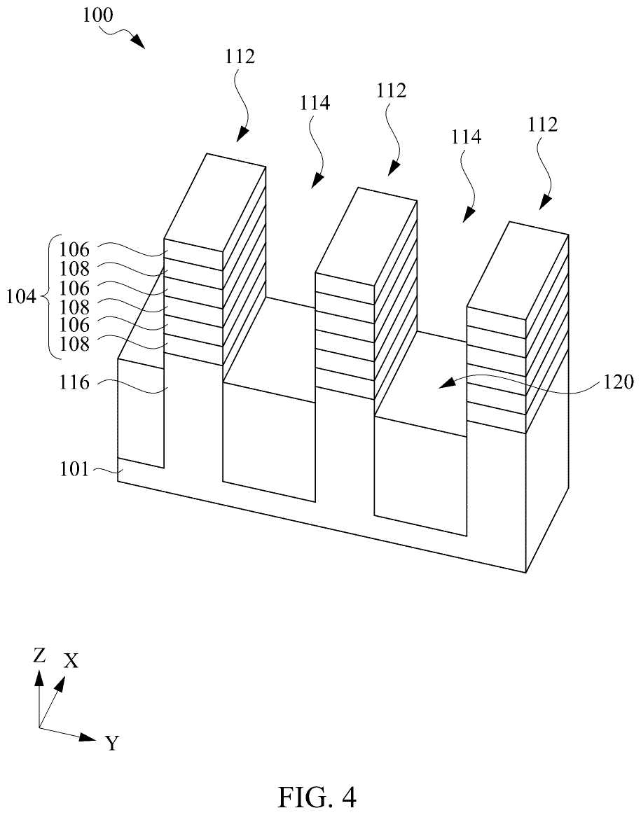

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the shallow trench isolation (STI) regions.

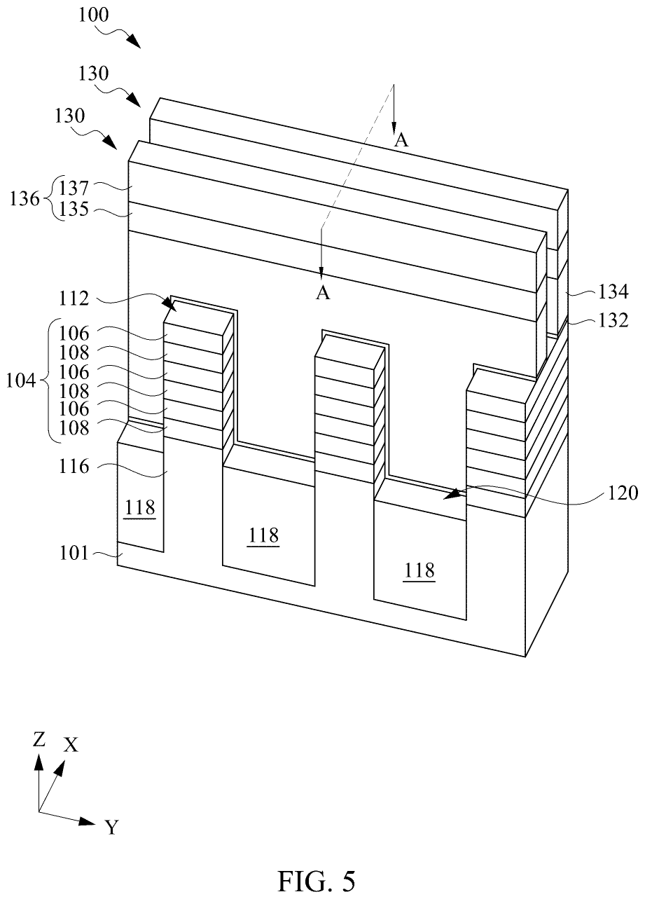

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The first portions of the fin structures 112 that are covered by the sacrificial gate electrode layer 134 of the sacrificial gate structure 130 serve as channel regions for the semiconductor device structure 100.

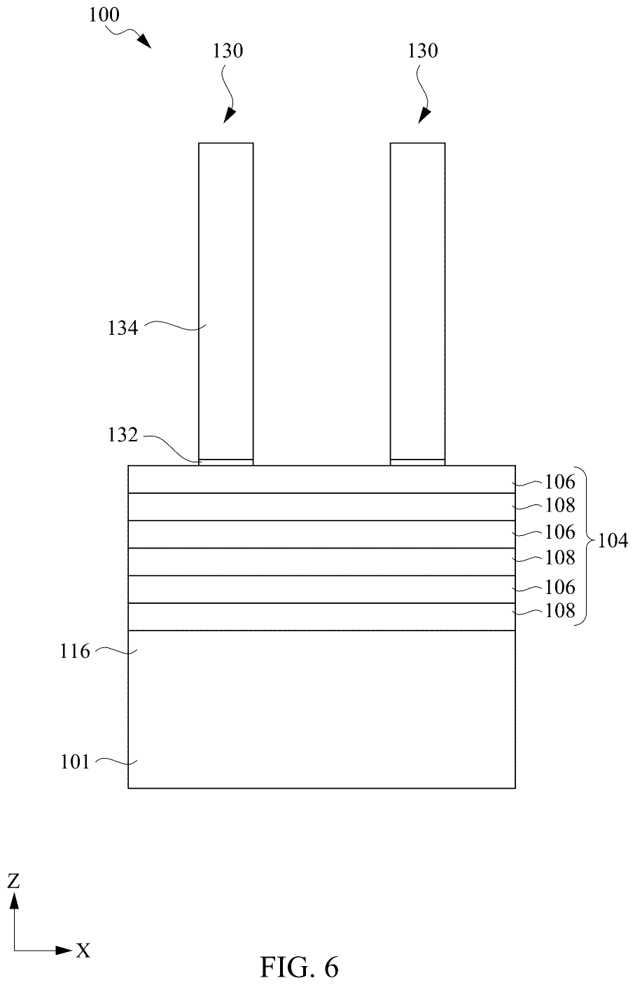

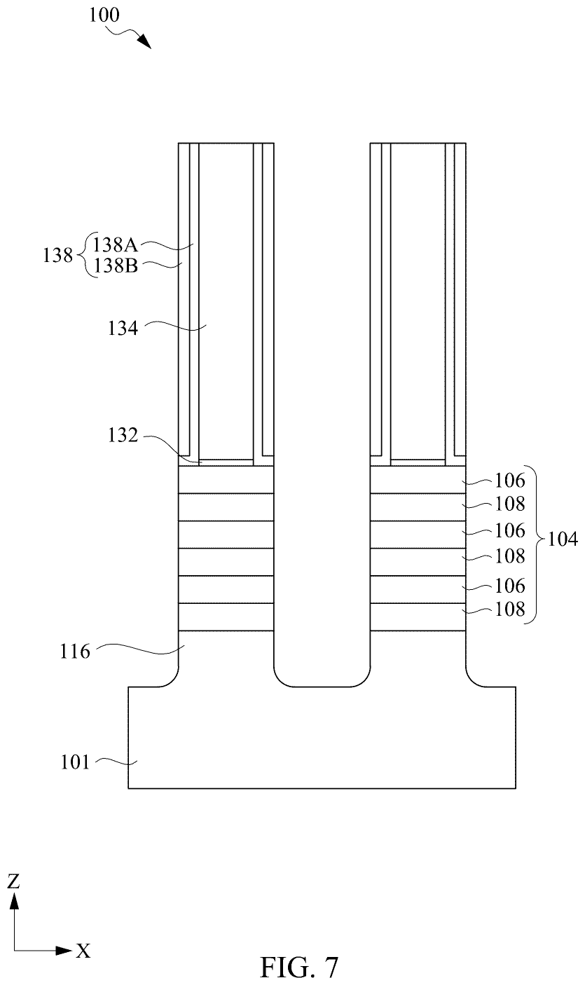

FIGS. 6, 7, 8, 9, 10, 11, 12, 13, 14, 15, and 16 are cross-sectional side views of the semiconductor device structure 100 taken along line A-A of FIG. 5, in accordance with some embodiments. As shown in FIG. 6, the sacrificial gate structures 130 includes the sacrificial gate dielectric layer 132 and the sacrificial gate electrode layer 134, and the mask layer 136 is omitted for clarity. Next, as shown in FIG. 7, spacers 138 are formed on sidewalls of the sacrificial gate structures 130. The spacers 138 may be formed by conformally depositing one or more layers, such as first spacer 138A and second spacer 138B, as shown in FIG. 7, and then anisotropic etching the one or more layers, for example. The spacers 138A, 138B may be made of a dielectric material such as silicon oxide, silicon nitride, silicon carbide, silicon oxynitride, SiCN, silicon oxycarbide, SiOCN, and/or combinations thereof.

As shown in FIG. 7, the second portions of the fin structures 112 not covered by the sacrificial gate structure 130 and the spacers 138 are recessed to a level above, at, or below the top surfaces of the isolation regions 120 (FIG. 5). The recessing of the second portions of the fin structures 112 can be done by an etch process, either isotropic or anisotropic etch process, and the etch process may be selective with respect to the semiconductor materials of the first and second semiconductor layers 106, 108. The etch process may be a dry etch, such as a RIE, NBE, or the like, or a wet etch, such as using tetramethyalammonium hydroxide (TMAH), ammonium hydroxide (NH₄OH), or any suitable etchant.

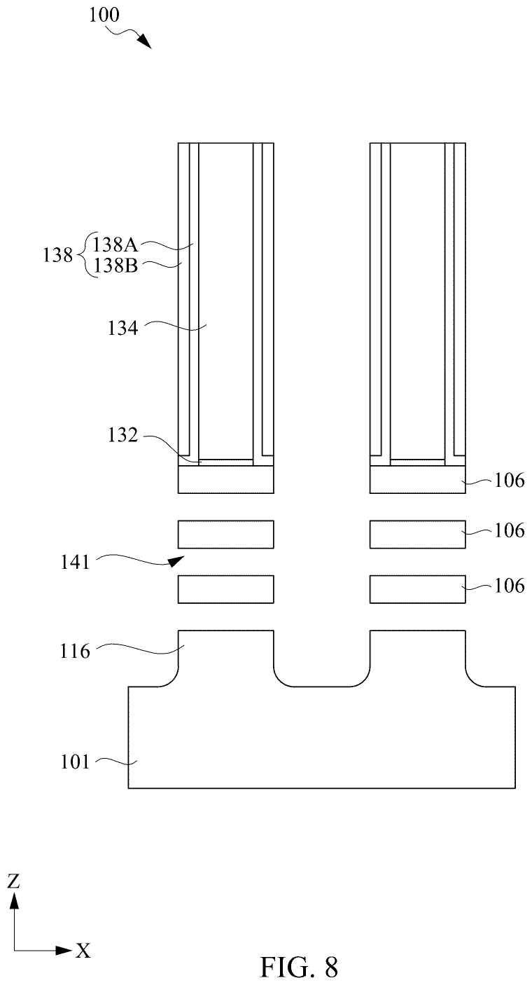

Next, as shown in FIG. 8, the second semiconductor layers 108 are removed. The second semiconductor layers 108 may be removed by a selective etch process, such as a selective dry etch process, a selective wet etch process, or a combination thereof. In some embodiments, the selective etch process does not substantially affect the first semiconductor layers 106. The removal of the second semiconductor layers 108 form openings 141 between vertically adjacent first semiconductor layers 106, as shown in FIG. 8.

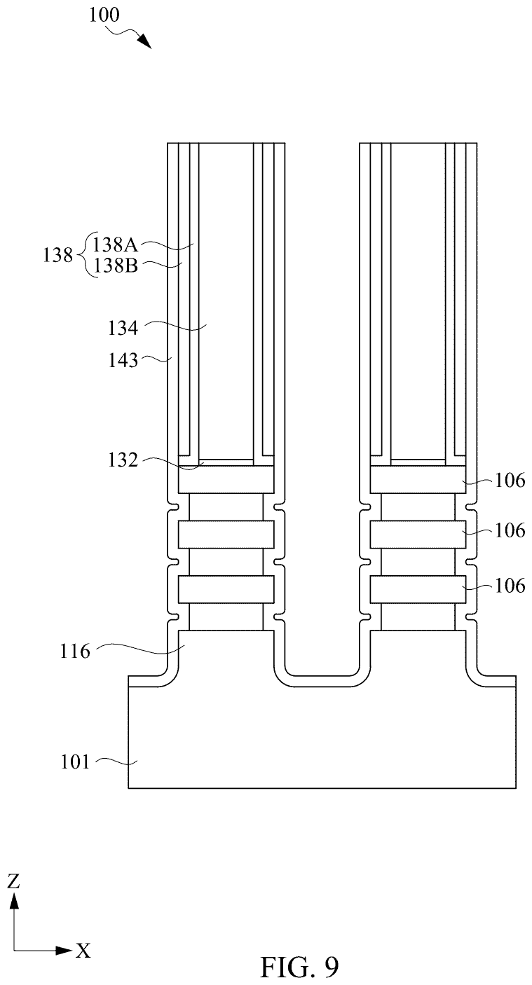

In FIG. 9, a dielectric material 143 is formed in the openings 141 and on the exposed surfaces of the semiconductor device structure 100. In some embodiments, the dielectric material 143 is an oxide formed by any suitable process, such as ALD, CVD, PECVD, or FCVD. In some embodiments, the oxide is silicon oxide, such as a porous silicon oxide.

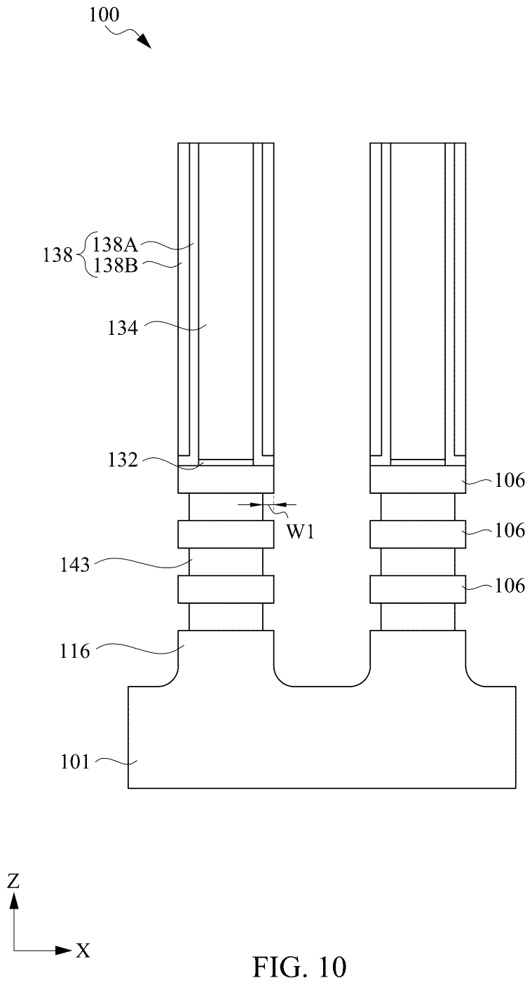

In FIG. 10, an etch back process is performed to remove portions of the dielectric material 143 other than the portions of the dielectric material 143 formed between vertically adjacent first semiconductor layers 106. In some embodiments, the etch back process is an anisotropic etching process. At this stage, edge portions of the dielectric material 143 and edge portions of the first semiconductor layers 106 have substantially flat surfaces which may be flush with side surfaces of the spacers 138. Next, as shown in FIG. 10, edge portions of the dielectric material 143 are removed horizontally along the X direction. In other words, the dielectric material 143 is recessed along the X direction. The removal of the edge portions of the dielectric material 143 forms cavities. In some embodiments, the edge portions of the dielectric material 143 are removed by a selective wet etch process. In some embodiments, the cavity has a width W1 along the X direction, as shown in FIG. 10.

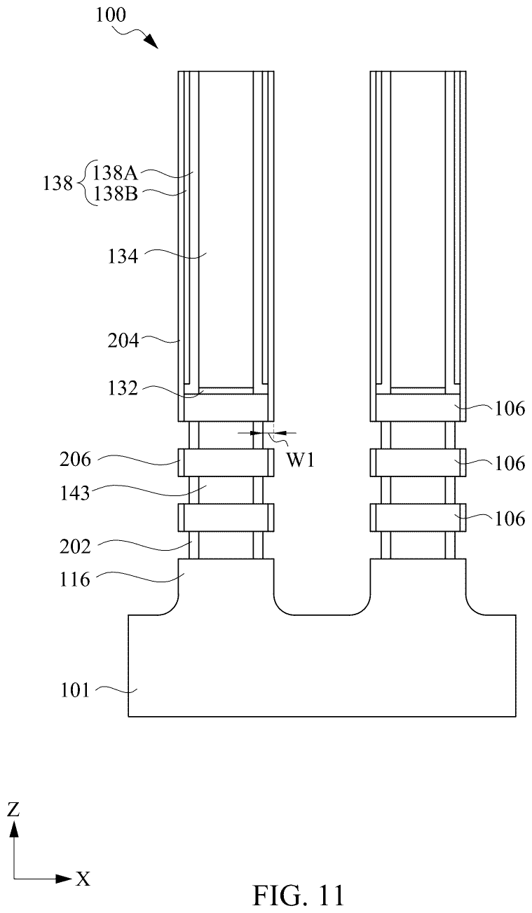

As shown in FIG. 11, an implantation process is performed to implant a dopant into the dielectric material 143. The dopant is implanted into the dielectric material 143 to form regions 202 having increased etch selectivity between the regions 202 of the dielectric material 143 and the rest of the dielectric material 143. In some embodiments, the regions 202 are edge regions of the dielectric material 143, and the rest of the dielectric material 143 may be a center region of the dielectric material 143, as shown in FIG. 11. In some embodiments, the width of the region 202 along the X direction is smaller than the width of the center region of the dielectric material 143 along the X direction. For example, a ratio of the width of the region 202 to the width of the center region of the dielectric material 143 may be between about 1:1000 and 1:20. The regions 202 of the dielectric material 143 may be doped regions, while the center region of the dielectric material 143 is undoped. In some embodiments, the dopant is a metal, such as Al, La, Ti, Zr, Hf, or other suitable metal, and the region 202 includes a metal doped oxide, such as metal doped silicon oxide. As described above, in some embodiments, the dielectric material 143 includes silicon oxide. Thus, the metal doped silicon oxide of the region 202 would not be substantially affected by an etch process that removes the silicon oxide of the rest of the dielectric material 143. In some embodiments, the dopant concentration in the region 202 may decrease in a direction towards the rest of the dielectric material 143.

In some embodiments, the spacers 138 and the first semiconductor layers 106 are also implanted with the dopant, and regions 204, 206 are formed in the spacers 138 and the first semiconductor layers 106, respectively. The regions 204 may include a metal doped dielectric material of the second spacer 138B (or second spacer 138B and first spacer 138A if the metal dopant is also diffused into the first spacer 138A). The region 206 may include a metal doped semiconductor material, such as metal doped silicon. In some embodiments, the dopant is easier to be implanted into a dielectric material than a semiconductor material. As a result, a width of the region 202 along the X direction is greater than a width of the region 206 (or a width of the region 204) along the X direction. In some embodiments, the implantation process may be tuned so the dopant is implanted into the porous material of the dielectric material 143 but not the materials of the spacer 138 and the first semiconductor layers 106. As a result, the spacers 138 and the first semiconductor layers 106 are substantially free of the dopant. In other words, the regions 204, 206 do not exist in some embodiments. The implantation process may be tuned by reducing the implantation energy, the processing duration, or other suitable process parameters.

In some embodiments, instead of an implantation process, a treatment process may be performed to form the regions 202. For example, the treatment process may be a nitridation process. The nitridation process may be a thermal nitridation process, a plasma nitridation process, a radical nitridation process, or other suitable nitridation process. As a result of the nitridation process, the regions 202 of the dielectric material 143 include silicon nitride with a nitrogen concentration decreasing in a direction towards the rest of the dielectric material 143. In some embodiments, the spacer 138 and the first semiconductor layers 106 may be also nitridated. As a result, the region 204 of the spacer 138 includes a higher concentration of nitrogen compared to the rest of the spacer 138, and the regions 206 of the first semiconductor layer 106 are converted to silicon nitride. In some embodiments, similar to the implantation process, the nitridation process may be controlled so that dielectric materials are easier to be nitridated than a semiconductor material. As a result, a width of the region 202 along the X direction is greater than a width of the region 206 (or a width of the region 204) along the X direction. In some embodiments, the nitridation process may be tuned so the porous material of the dielectric material 143 is nitridated, while the materials of the first semiconductor layers 106 and the spacers 138 are not nitridated. As a result, the first semiconductor layers 106 are substantially free of nitrogen, and the nitrogen concentration of the spacer 138 is not substantially changed. In other words, the regions 204, 206 do not exist in some embodiments. The nitridation process may be tuned by reducing the processing temperature, plasma power, processing duration, or other suitable process parameters.

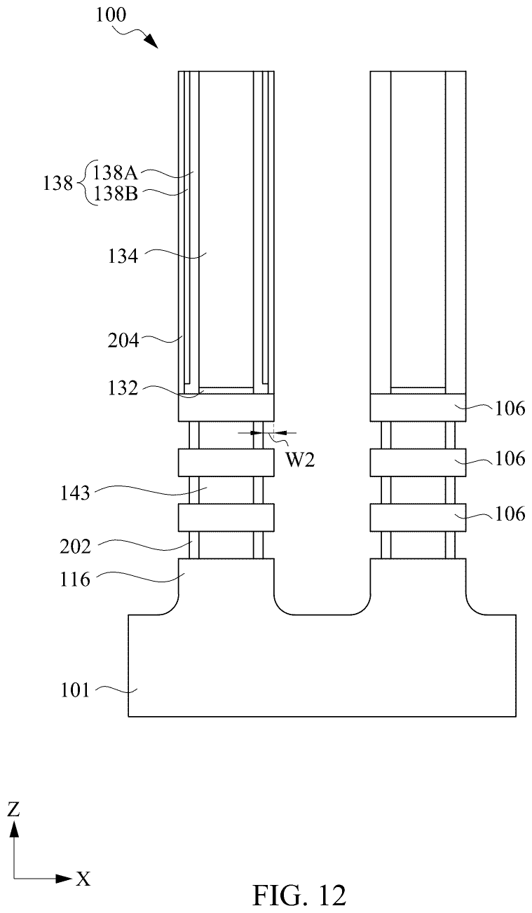

In the embodiments where the regions 206 are formed in the first semiconductor layers 106, an etch process may be performed to remove the doped regions 206. In some embodiments, the etch process may be a selective etch process that removes the semiconductor material but not dielectric materials. In some embodiments, the etch process removes a portion of the doped region 202 and a portion of the doped region 204, while the doped region 206 is completely removed due to its smallest width, as shown in FIG. 12. After the removal of the doped regions 206, the cavity has a width W2, which may be smaller than the width W1 or the same as the width W1.

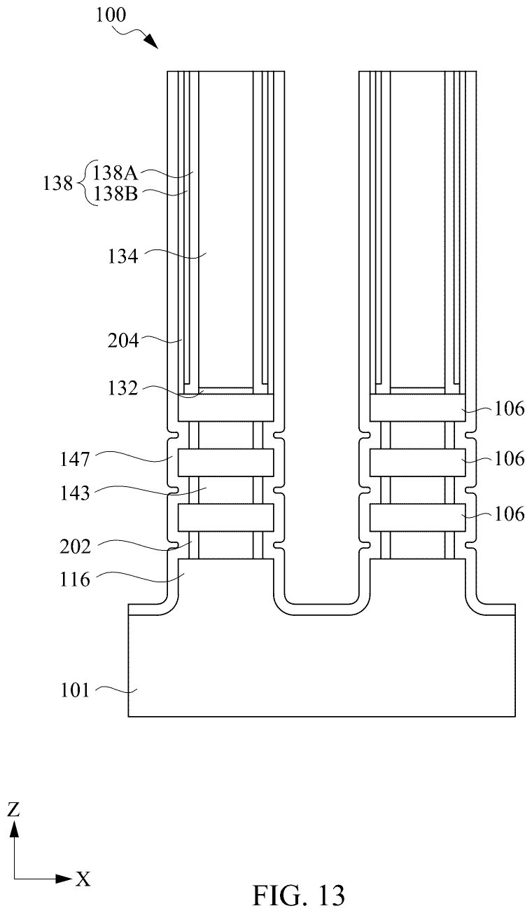

In FIG. 13, a dielectric layer 147 is deposited in the cavities. The dielectric layer 147 may be made of a dielectric material, such as SION, SiCN, SiOC, SiOCN, or SiN. The dielectric layer 147 may be formed by a conformal deposition process, such as ALD. In some embodiments, the dielectric layer 147 and the region 202 of the dielectric material 143 include different materials or same material with different compositions. For example, in some embodiments, the region 202 of the dielectric material 143 includes metal doped silicon oxide, which is different from the material of the dielectric layer 147. In some embodiments, the region 202 of the dielectric material 143 includes silicon nitride having a first nitrogen concentration, and the dielectric layer 147 may include a material other than silicon nitride or silicon nitride with a second nitrogen concentration different from the first nitrogen concentration.

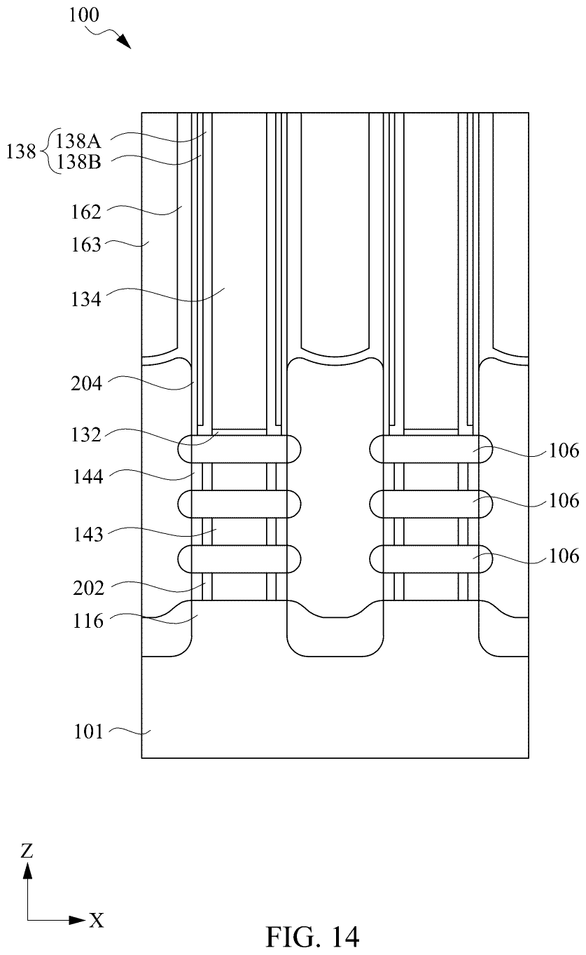

In FIG. 14, dielectric spacers 144 are formed by removing portions of the dielectric layer 147. In some embodiments, the portions of the dielectric layer 147 are removed by an anisotropic etching process. The dielectric spacers 144 are protected by the first semiconductor layers 106 during the anisotropic etching process. The dielectric material 143 is capped between the dielectric spacers 144 along the X direction, as shown in FIG. 14. In some embodiments, the doped regions 202 of the dielectric material 143 are in contact with the dielectric spacers 144.

Next, as shown in FIG. 14, source/drain (S/D) regions 146 are formed over the substrate 101. In some embodiments, the S/D regions 146 may grow both vertically and horizontally to form facets, which may correspond to crystalline planes of the material used for the substrate 101. In this disclosure, a source region and a drain region are interchangeably used, and the structures thereof are substantially the same. Furthermore, source/drain region(s) may refer to a source or a drain, individually or collectively dependent upon the context. In some embodiments, the S/D regions 146 are n-type S/D epitaxial features and may be made of one or more layers of Si, SiP, SiC and SiCP for n-channel FETs. In some embodiments, the S/D regions 146 are p-type epitaxial features and may be made of one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. The S/D region 146 may include doped and undoped epitaxial materials.

Next, a contact etch stop layer (CESL) 162 is conformally formed on the exposed surfaces of the semiconductor device structure 100, as shown in FIG. 14. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

In some embodiments, the regions 204 of the spacer 138 is in contact with the S/D regions 146 and the CESL 162, as shown in FIG. 14. In some embodiments, the regions 204 are not present.

A planarization process is performed to expose the sacrificial gate electrode layer 134, as shown in FIG. 14. The planarization process may be any suitable process, such as a CMP process. The planarization process removes portions of the ILD layer 163 and the CESL 162 disposed on the sacrificial gate structures 130. The planarization process may also remove the mask layer 136 (FIG. 5).

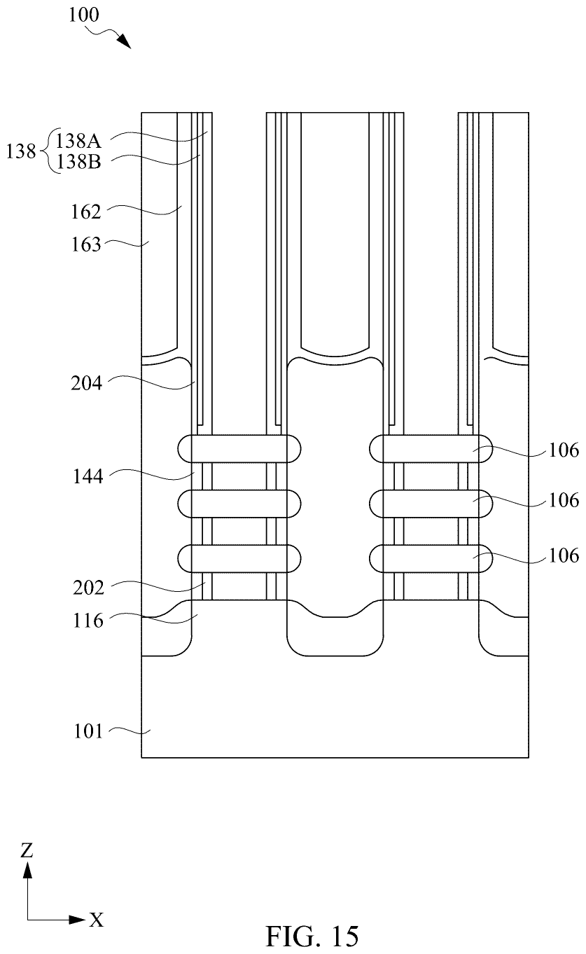

In FIG. 15, the sacrificial gate electrode layer 134, the sacrificial gate dielectric layer 132, and a portion of the dielectric material 143 are removed, exposing portions of the first semiconductor layer 106. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 138, the ILD layer 163, and the CESL 162. In some embodiments, the portion of the dielectric material 143 is removed by a selective etch process. The selective etch process removes the portion of the dielectric material 143 between the first semiconductor layers 106 but does not remove the first semiconductor layers 106, the ILD layer 163, the CESL 162, and the spacers 138. In some embodiments, the sacrificial gate dielectric layer 132 and the portion of the dielectric material 143 are removed by the same selective etch process.

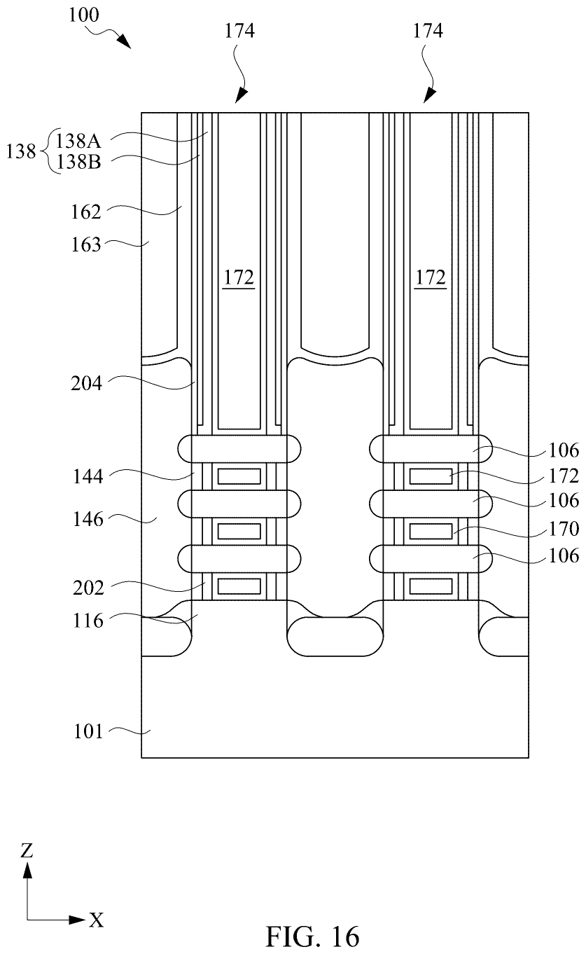

In some embodiments, the regions 202 of the dielectric material 143 are not removed due to the different etch selectivity between the material of the regions 202 and the material of the rest of the dielectric material 143. In some embodiments, the regions 202 of the dielectric material 143 are also removed by the selective etch process, but the dielectric spacers 144 are not affected by the selective etch process. The regions 202 of the dielectric material 143 protect the dielectric spacers 144 during the selective etch process. As a result, the risk of current leakage between the gate electrode layer 172 (FIG. 16) and the S/D regions 146 is reduced. Furthermore, the enhanced dielectric spacers 144 robustness during the process to remove the portions of the dielectric material 143 provides enlarged epi-proximity-push and junction-overlap capability, which is positive for device performance optimization.

As shown in FIG. 15, portions of the first semiconductor layer 106 may be exposed after the removal of the portions of the dielectric material 143. Each first semiconductor layer 106 may be a nanostructure channel.

In FIG. 16, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 163. The gate dielectric layer 170 and the gate electrode layer 172 formed over the ILD layer 163 are then removed by using, for example, CMP, until the top surface of the ILD layer 163 is exposed.

In some embodiments, as shown in FIG. 16, the gate dielectric layer 170 is in contact with the regions 202 of the dielectric material 143. For example, the gate dielectric layer 170 is capped between two regions 202 along the X direction, while the two regions 202 are capped between two dielectric spacers 144 along the X direction, as shown in FIG. 16. In some embodiments, the gate dielectric layer 170 includes a first metal, and the region 202 of the dielectric material 143 includes a second metal. The first metal may be the same as the second metal or different from the second metal. In some embodiments, the metal concentration in the region 202 of the dielectric material 143 decreases in a direction from the dielectric spacer 144 towards the gate dielectric layer 170 along the X direction. In some embodiments, the gate structure 174 has a gate length along the X direction, and the gate length may be the same as the width of the center portion of the dielectric material 143 described in FIG. 11. Thus, in some embodiments, a ratio of the width of the region 202 to the gate length of the gate structure 174 may be between about 1:1000 and 1:20. If the ratio is less than about 1:1000, the width of the region 202 may be too small to protect the dielectric spacers 144. On the other hand, if the ratio is greater than about 1:20, the gate length is too small, which may lead to performance issues.

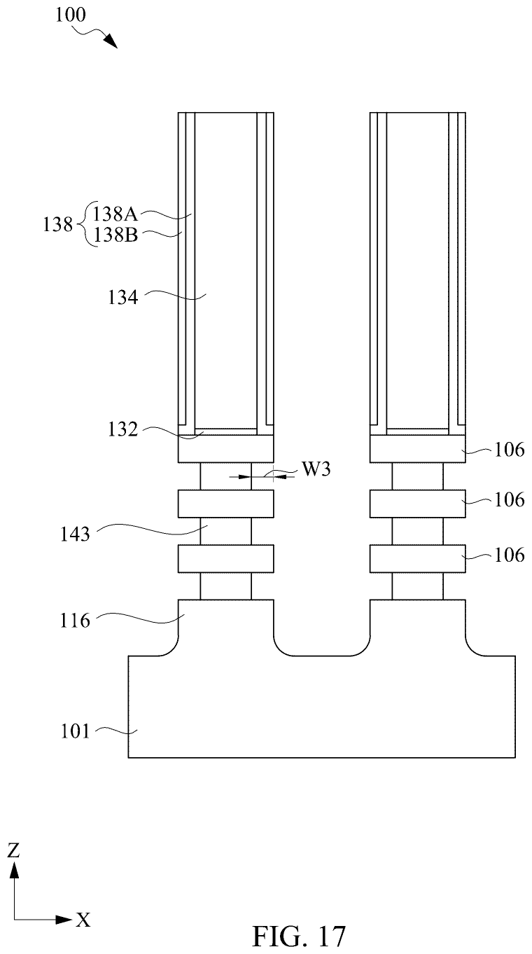

FIGS. 17, 18, 19, and 20 are cross-sectional side views of the semiconductor device structure 100 taken along line A-A of FIG. 5, in accordance with alternative embodiments. As shown in FIG. 17, the dielectric material 143 is laterally recessed to form cavities between vertically adjacent first semiconductor layers 106. The cavity has a width W3 along the X direction. The width W3 is greater than the width W1 shown in FIG. 10. In other words, more dielectric material 143 is removed along the X direction than the process described in FIG. 10.

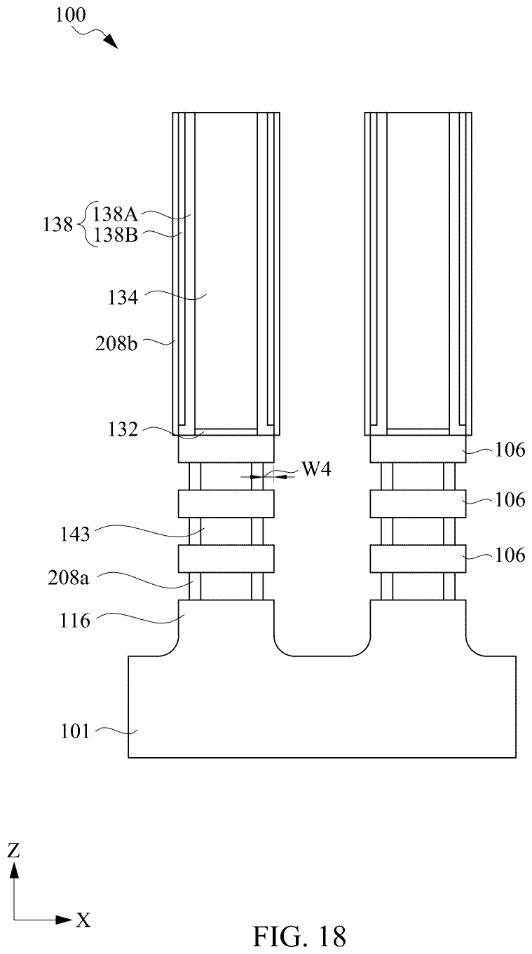

In FIG. 18, a dielectric layer 208a is deposited in the cavities between the vertically adjacent first semiconductor layers 106. The dielectric layer 208a does not fill the cavities. In some embodiments, after the deposition of the dielectric layer 208a, the cavity has a width W4 along the X direction, as shown in FIG. 18. The dielectric layer 208a includes any suitable dielectric material having different etch selectivity compared to that of the dielectric material 143. Thus, the dielectric layer 208a is not substantially affected during the subsequent removal of the dielectric material 143. In some embodiments, the dielectric layer 208a is a metal-containing dielectric layer, such as a metal oxide layer, a metal nitride layer, a metal oxynitride layer, a metal nitricarbide layer, or a metal oxynitricarbide layer. The metal of the metal-containing dielectric layer may include any suitable metal, such as Hf, Zr, Ti, La, or Al. In some embodiments, the dielectric layer 208a is a silicon-containing dielectric layer, such as a silicon nitride (SiN) layer, a silicon oxynitride (SiON) layer, a silicon nitricarbide (SiNC) layer, or a silicon oxynitricarbide (SiONC) layer.

In some embodiments, the dielectric layer 208a is selectively formed on the dielectric material 143. For example, a treatment process may be first performed to cause functionalization of the surfaces of the dielectric material 143 to improve selectivity before the deposition of the dielectric layer 208a. The treatment process may be wet diluted HF treatment, dry hydrogen process (plasma or thermal), or other suitable process that can improve selectivity of the dielectric layer 208a being deposited on the dielectric material 143. In some embodiments, with the treatment process, no material is deposited on the first semiconductor layers 106 and the spacers 138 during the deposition of the dielectric layer 208a. The dielectric layer 208a may be deposited by any suitable process. In some embodiments, an atomic layer deposition (ALD) process is performed to deposit the dielectric layer 208a. Typically, a layer formed by an ALD process is a substantially conformal layer. However, due to the treatment process, the dielectric layer 208a is selectively deposited on the dielectric material 143 by the ALD process. Thus, in some embodiments, the ALD process form discrete dielectric layers 208a on the dielectric material 143, as shown in FIG. 18. In some embodiments, with the treatment process, a dielectric layer 208b is deposited on the spacers 138, and a dielectric layer (not shown) is deposited on the first semiconductor layers 106. As a result of the treatment process, a width of the dielectric layer 208a along the X direction is substantially greater than a width of the dielectric layer 208b, which is substantially greater than a width of the dielectric layer deposited on the first semiconductor layers 106. Thus, in some embodiments, a non-conformal dielectric layer is deposited by an ALD process. In some embodiments, an etch process may be performed after the deposition of the non-conformal dielectric layer to remove the dielectric layer deposited on the first semiconductor layers 106. The etch process may be any suitable etch process. In some embodiments, the etch process is a wet metal oxide removal process or gas-phase metal oxide removal process. The dielectric layers 208a, 208b may be recessed by the etch process. In some embodiments, due to the different thicknesses, the dielectric layer formed on the first semiconductor layers 106 is removed, and the dielectric layers 208a, 208b remain, as shown in FIG. 18. The dielectric layers 208a, 208b may include the same material because the dielectric layers 208a, 208b are formed by the same deposition process.

In some embodiments, the treatment process, the deposition process, and the etch process are repeated to improve selectivity of the dielectric layer 208a. In other words, the dielectric layer 208a may be formed by a cyclic process, and each cycle includes the treatment process, the deposition process, and the etch process. In such embodiments, the thickness of the dielectric layer 208a formed in each cycle may be small, such as from about several angstroms to about 20 angstroms, and the thickness of the dielectric layer formed on the first semiconductor layers 106 may be even smaller. The etch process of each cycle may have a short duration, such as from about 1 second to about several tens of seconds. In some embodiments, the dielectric layer 208b is removed as a result of the cyclic process, because the dielectric layer 208b is more exposed to the etchants of the etch process than the dielectric layer 208a.

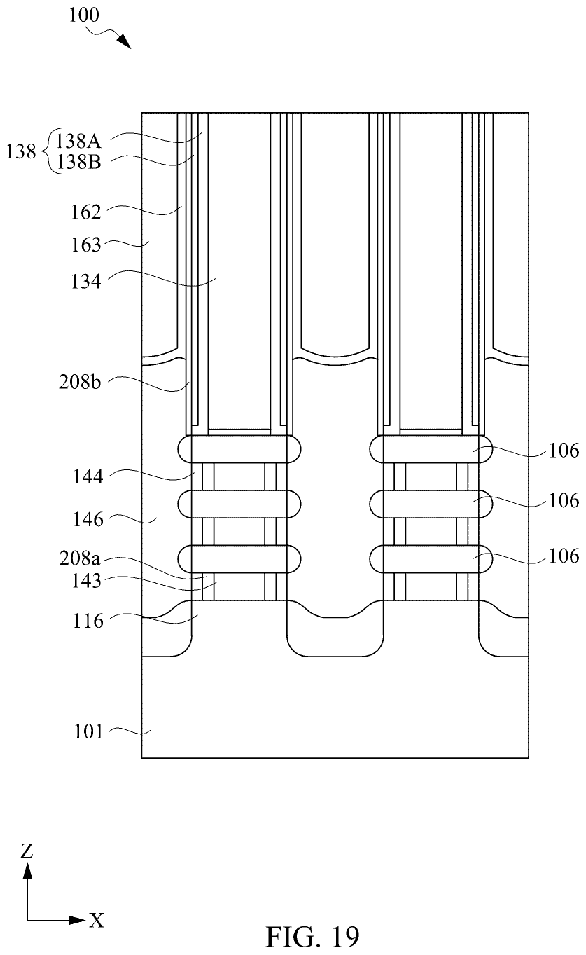

In FIG. 19, the dielectric spacers 144 are formed to cap the dielectric layer 208a and the dielectric material 143. The S/D regions 146, the CESL 162, and the ILD layer 163 are formed. In some embodiments, the dielectric layer 208b is disposed between the CESL 162 and the spacer 138. In some embodiments, the dielectric layer 208b is not present.

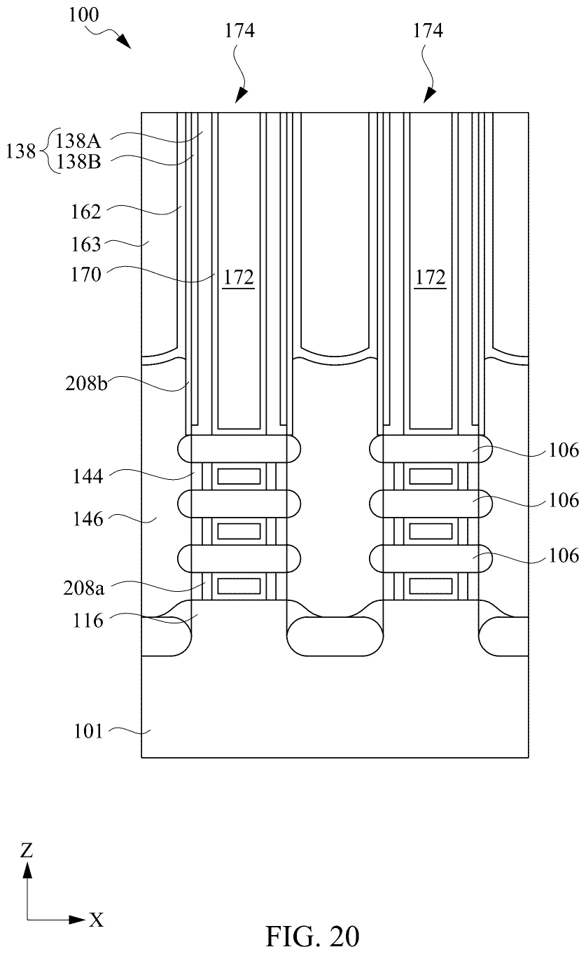

In FIG. 20, the sacrificial gate structure 130 and the dielectric material 143 are removed, and the gate structures 174 are formed. In some embodiments, the dielectric layer 208a is not removed due to the different etch selectivity between the material of the dielectric layer 208a and the material of the dielectric material 143. In some embodiments, the dielectric layer 208a is also removed during the removal of the dielectric material 143, but the dielectric spacers 144 are not affected. The dielectric layer 208a protects the dielectric spacers 144 during the removal of the dielectric material 143. As a result, the risk of current leakage between the gate electrode layer 172 (FIG. 16) and the S/D regions 146 is reduced. Furthermore, the enhanced dielectric spacers 144 robustness during the process to remove the portions of the dielectric material 143 provides enlarged epi-proximity-push and junction-overlap capability, which is positive for device performance optimization.

In some embodiments, as shown in FIG. 20, the gate dielectric layer 170 is in contact with the dielectric layer 208a. For example, the gate dielectric layer 170 is capped between two dielectric layers 208a along the X direction, while the two dielectric layers 208a are capped between two dielectric spacers 144 along the X direction, as shown in FIG. 20. In some embodiments, the gate dielectric layer 170 includes a first metal, and the dielectric layer 208a includes a second metal. The first metal may be the same as the second metal or different from the second metal.

Embodiments of the present disclosure provide a semiconductor device structure and methods of forming the same. The structure includes a gate dielectric layer 170 disposed between first semiconductor layers 106, two regions 202 or dielectric layers 208a disposed on opposite sides of the gate dielectric layer 170, and two dielectric spacers 144. The gate dielectric layer 170 and the two regions 202 or dielectric layers 208a are disposed between the two dielectric spacers 144. Some embodiments may achieve advantages. For example, the regions 202 or the dielectric layers 208a has a different etch selectivity compared to the dielectric material 143. Thus, the dielectric spacers 144 are protected by the regions 202 or the dielectric layers 208a during the removal of the dielectric material 143. As a result, the risk of current leakage between the gate electrode layer 172 and the S/D regions 146 is reduced.

An embodiment is a semiconductor device structure. The structure includes a first semiconductor layer, a second semiconductor layer disposed over the first semiconductor layer, a gate dielectric layer disposed between the first and second semiconductor layers, and first and second regions of a dielectric material disposed on opposite sides of the gate dielectric layer. The first region of the dielectric material includes a first metal, and a concentration of the first metal in the first region decreases in a direction towards the gate dielectric layer. The structure further includes first and second dielectric spacers, and the gate dielectric layer and the first and second regions of the dielectric material are disposed between the first and second dielectric spacers.

Another embodiment is a semiconductor device structure. The structure includes a first semiconductor layer, a second semiconductor layer disposed over the first semiconductor layer, a gate electrode layer disposed between the first and second semiconductor layers, and first and second dielectric layers disposed on opposite sides of the gate electrode layer. The first dielectric layer includes a metal, and the first and second dielectric layers are discrete. The structure further includes first and second dielectric spacers, and the gate electrode layer and the first and second dielectric layers are disposed between the first and second dielectric spacers.

A further embodiment is a method. The method includes forming a fin structure from a substrate, and the fin structure includes alternating first and second semiconductor layers. The method further includes removing the second semiconductor layers, forming a dielectric material between the first semiconductor layers, laterally recessing the dielectric material, and forming edge regions of the dielectric material. The edge regions of the dielectric material have a different composition than a center region of the dielectric material. The method further includes forming dielectric spacers on opposite sides of the dielectric material and removing the center region of the dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first semiconductor layer;
a second semiconductor layer disposed over the first semiconductor layer;
a gate dielectric layer disposed between the first and second semiconductor layers;
first and second regions of a dielectric material disposed on opposite sides of the gate dielectric layer, wherein the first region of the dielectric material comprises a first metal, and a concentration of the first metal in the first region decreases in a direction towards the gate dielectric layer; and
first and second dielectric spacers, wherein the gate dielectric layer and the first and second regions of the dielectric material are disposed between the first and second dielectric spacers.

2. The semiconductor device structure of claim 1, wherein the first metal comprises Hf, Zr, Ti, La, or Al.

3. The semiconductor device structure of claim 1, wherein the gate dielectric layer comprises a second metal.

4. The semiconductor device structure of claim 3, wherein the first metal and the second metal are same.

5. The semiconductor device structure of claim 3, wherein the first metal and the second metal are different.

6. The semiconductor device structure of claim 1, further comprising a spacer disposed over the second semiconductor layer.

7. The semiconductor device structure of claim 6, wherein the spacer comprises a third region including the first metal.

8. The semiconductor device structure of claim 7, further comprising a gate electrode layer disposed on the gate dielectric layer, wherein the gate electrode layer and the gate dielectric layer are disposed adjacent the spacer.

9. A semiconductor device structure, comprising:
a first semiconductor layer;
a second semiconductor layer disposed over the first semiconductor layer;
a gate electrode layer disposed between the first and second semiconductor layers;
first and second dielectric layers disposed on opposite sides of the gate electrode layer, wherein the first dielectric layer comprises a metal, and the first and second dielectric layers are discrete; and
first and second dielectric spacers, wherein the gate electrode layer and the first and second dielectric layers are disposed between the first and second dielectric spacers.

10. The semiconductor device structure of claim 9, wherein the metal comprises Hf, Zr, Ti, La, or Al.

11. The semiconductor device structure of claim 10, wherein the first dielectric layer is an oxide layer, a nitride layer, an oxynitride layer, a nitricarbide layer, or an oxynitricarbide layer.

12. The semiconductor device structure of claim 9, further comprising a spacer disposed over the second semiconductor layer.

13. The semiconductor device structure of claim 12, further comprising a third dielectric layer adjacent the spacer, wherein the spacer is disposed between the third dielectric layer and the gate electrode layer.

14. The semiconductor device structure of claim 13, wherein the third dielectric layer and the first dielectric layer comprise a same material.

15. The semiconductor device structure of claim 13, further comprising a contact etch stop layer in contact with the third dielectric layer.

16. A method for forming a semiconductor device structure, comprising:
forming a fin structure from a substrate, wherein the fin structure comprises alternating first and second semiconductor layers;
removing the second semiconductor layers;
forming a dielectric material between the first semiconductor layers;
laterally recessing the dielectric material;
forming edge regions of the dielectric material, wherein the edge regions of the dielectric material have a different composition than a center region of the dielectric material;
forming dielectric spacers on opposite sides of the dielectric material; and
removing the center region of the dielectric material.

17. The method of claim 16, wherein the forming of the edge regions of the dielectric material comprises an implantation process or a nitridation process.

18. The method of claim 17, wherein the implantation process implants a dopant into the dielectric material.

19. The method of claim 18, wherein the dopant is a metal.

20. The method of claim 18, further comprising forming a region in a spacer disposed over the first semiconductor layers by the implantation process or nitridation process.
